(19) United States
(12) Patent Application Publication
(10) Pub. No.: US 2014/0196659 A1
(43) Pub. Date: Jul. 17, 2014

(54) APPARATUS FOR FABRICATING INGOT AND METHOD FOR FABRICATING INGOT

(71) Applicant: L G INNOTEK CO., LTD., Seoul (KR)

(72) Inventors: Dong Geun Shin, Jung-gu (KR); Chang Hyun Son, Jung-gu (KR)

(73) Assignee: LG INNOTEK CO., LTD., Seoul (KR)

(21) Appl. No.: 14/124,996

(22) PCT Filed: Jun. 7, 2012
(86) PCT No.: PCT/KR2012/004481

§ 371 Date: Mar. 3, 2014

(30) Foreign Application Priority Data
Jun. 7, 2011 (KR) 10-2011-0054628

(51) Int. Cl. C30B 23/00

(52) U.S. Cl. CPC C30B 23/007
USPC 117/87; 118/726

(57) ABSTRACT

An apparatus for fabricating an ingot includes a crucible for receiving a raw material, wherein the raw material has a shape extending in one direction.

### TECHNICAL FIELD

The disclosure relates to an apparatus for fabricating an ingot and a method for fabricating the ingot.

### BACKGROUND ART

In general, materials are very important factors to determine the property and the performance of final products in the electric, electronic and mechanical industrial fields

SiC represents the superior thermal stability and superior oxidation-resistance property. In addition, the SiC has the superior thermal conductivity of about 4.6 W/Cm° C., so the SiC can be used for fabricating a large-size substrate having a diameter of about 2 inches or above. In particular, the single crystal growth technology for the SiC is very stable actually, so the SiC has been extensively used in the industrial field as a material for a substrate.

In order to grow the single crystal for SiC, a seeded growth sublimation scheme has been suggested. In this case, after putting a raw material in a crucible, and a SiC single crystal serving as a seed is provided on the raw material. Temperature gradient is formed between the raw material and the seed, so that the raw material in the crucible is dispersed to the seed, and re-crystallized to grow a single crystal.

When the SiC single crystal is grown, SiC powders are typically used as a raw material. When the SiC powders are used as a raw material, two much time is spent to synthesize the SiC powder. In addition, when the SiC powders are filled in the crucible, impurities are introduced, exerting an influence upon the quality of the single crystal.

### DISCLOSURE OF INVENTION

### Technical Problem

The embodiment can grow a high-quality single crystal.

### Solution to Problem

An apparatus for fabricating an ingot according to the embodiment includes a crucible for receiving a raw material, wherein the raw material has a shape extending in one direction.

A method for fabricating an ingot according to the embodiment includes the steps of preparing a compound including silicon and carbon; converting the compound into a silicon carbide fiber; and growing the silicon carbide fiber in a single crystalline structure.

### Advantageous Effects of Invention

According to the apparatus for fabricating the ingot and the method for fabricating the ingot, the polymer containing Si and C may be used as a raw material to grow a single crystal. In detail, the raw material may include polycarbosilane. The fabricating time can be reduced and the fabricating process can be simplified by using the polycarbosilane as a raw material instead of using conventional SiC powder obtained from Si and C. This is because a synthesizing process to prepare the conventional SiC power can be omitted. In other words, the SiC raw material can be simultaneously synthesized and grown by using the polycarbosilane as a raw material.

Further, after synthesizing the SiC powder, the raw material can be prevented from being contaminated when the SiC powder is filled in the crucible. Therefore, impurities can be prevented from being introduced into the single crystal, so that a high-quality single crystal can be grown.

The embodiment may include empty spaces among the raw materials and form uniform thermal distribution in the raw material through the empty spaces. Further, a serious conglomeration phenomenon of the raw materials caused by sintering may be prevented, so that the raw material can be effectively sublimated and a supplying route for the raw materials can be provided. Thus, a sublimation ratio of the raw materials is increased at the same temperature condition, so that the single crystal can be effectively grown at the lower temperature.

Further, since the polycarbosilane is a fibrous material, the problem caused by dust derived from the powder may be prevented in advance. In addition, residual carbon may be prevented from being scattered and a fill factor of the reaction raw material may be attenuated, so that the reaction can be induced more smoothly and uniformly.

Since the fibrous polycarbosilane is used as the raw material, the raw material may be completely exhausted. Thus, in a process, the single crystal can be produced proportionally to the supplied raw material. Further, since the raw material is completely exhausted after producing the single crystal, it is not necessary to recovery and reuse the raw material, thereby preventing the cumbersome of the user.

Further, since the polycarbosilane is a fibrous material, sublimation reaction of the silicon carbide for growing the single crystal from an end of the fibrous material may be more effectively generated. Thus, a single crystal growth rate may be improved.

### BRIEF DESCRIPTION OF DRAWINGS

FIG. 1 is a sectional view of an apparatus for fabricating an ingot according to the embodiment;

FIG. 2 is a perspective view of a raw material according to the embodiment;

FIG. 3 is a view illustrating a molecular structure of polycarbosilane;

FIG. 4 is a flowchart showing a method for fabricating an ingot according to the embodiment; and

FIGS. 5 to 7 are sectional views illustrating a method for fabricating an ingot according to the embodiment.

### MODE FOR THE INVENTION

In the description of the embodiments, it will be understood that, when a layer (or film), a region, a pattern, or a structure is referred to as being “on” or “under” another substrate, another layer (or film), another region, another pad, or another pattern, it can be “directly” or over the other substrate, layer (or film), region, pad, or pattern, or one or more intervening layers may also be present. Such a position of the layer has been described with reference to the drawings.

Since the thickness and size of each layer shown in the drawings may be modified for the purpose of convenience or clarity of description, the size of elements does not utterly reflect an actual size.

Hereinafter, the embodiment of the present invention will be described with reference to accompanying drawings.

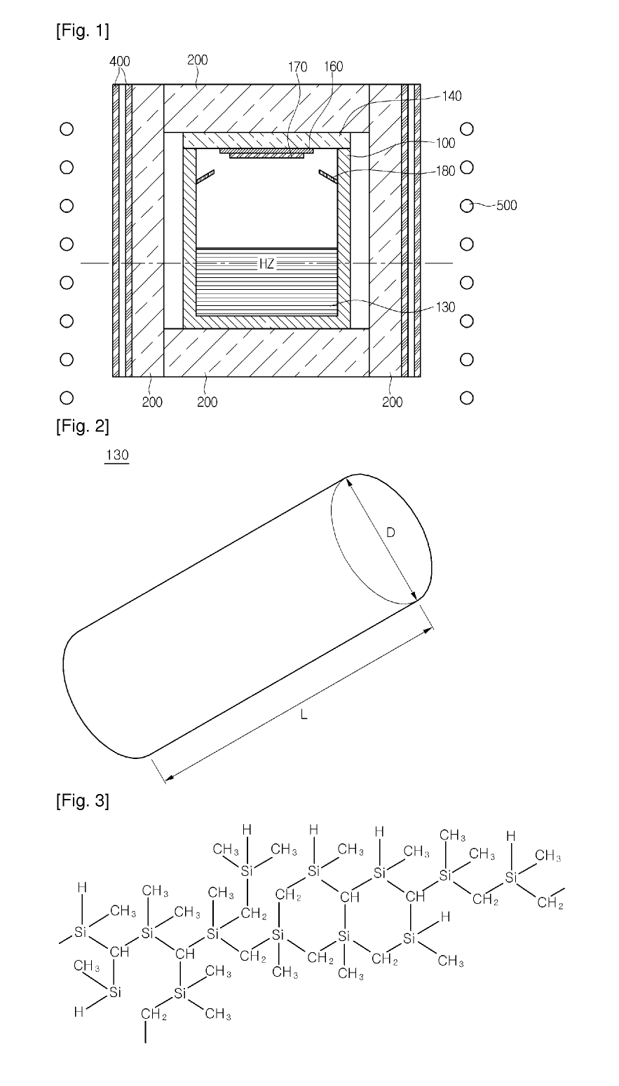

An apparatus for fabricating an ingot according to the embodiment will be described in detail with reference to FIGS. 1 to 3. FIG. 1 is a sectional view of an apparatus for fabricating an ingot according to the embodiment. FIG. 2 is a perspective view of a raw material according to the embodiment. FIG. 3 is a view illustrating a molecular structure of polycarbosilane.

Referring to FIGS. 1 to 3, the apparatus for fabricating the ingot according to the embodiment includes a crucible 100, a raw material 130, an upper cover 140, a seed holder 160, a focusing tube 180, a thermal insulator 200, a quartz pipe 400, and a heat generation induction part 500.

The crucible 100 may receive the raw material 130 therein.

The crucible 100 may have a cylindrical shape such that the crucible 100 can receive the raw material 130.

The crucible 100 may include a material having a melting point equal to or higher than the sublimation temperature of silicon carbide.

For example, the crucible 100 may be formed by using graphite.

Further, a material having a melting point equal to or higher than the sublimation temperature of silicon carbide may be coated on the graphite of the crucible 100. A material chemically inactive with respect to silicon and hydrogen at a temperature at which silicon carbide single crystal is grown is preferably used as the material coated on the graphite. For example, metal carbide or metal nitride may be used. Specifically, a mixture including at least two of Ta, Hf, Nb, Zr, W and V and carbide including carbon may be coated. Further, a mixture including at least two of Ta, Hf, Nb, Zr, W and V and nitride including nitrogen may be coated.

The raw material 130 has a shape extending in one direction.

The raw material 130 may have a column shape. In detail, the raw material may have a cylindrical shape. The raw material 130 may be a fibrous material.

The raw material 130 may have a shape which has a length L longer than a diameter D. An aspect ratio of the raw material 130 may become infinitely large. However, the embodiment is not limited thereto, and the raw material 130 may have various aspect ratios.

The diameter D of the raw material 130 may be in the range of 0.1 μm to 500 μm. In more detail, the diameter D of the raw material 130 may be in the range of 5 μm to 30 μm.

A plurality of raw materials 130 may be provided in the crucible 100. When the raw materials 130 are filled in the crucible 100, empty spaces (not shown and will not be shown hereinafter) may be formed among the raw materials 130. The thermal distribution may be uniformly formed in the raw material 130 due to the empty spaces. Further, a serious conglomeration phenomenon among the raw materials caused by sintering may be prevented, so that the raw materials can be effective sublimated and a supplying route for the raw materials may be provided. Thus, a sublimation ratio of the raw materials may be increased at the same temperature condition, so that the single crystal may be effectively grown at the lower temperature.

In detail, the raw material 130 may have a fill factor in the range of 10% to 90% in the crucible 100. In more detail, the raw material 130 may have a fill factor of 70% in the crucible 100.

The fill factor and size of the raw material 130 may exert an influence upon the silicon carbide sublimation rate. Therefore, the fill factor and size of the raw material 130 may be controlled according to a desired single crystal growth rate.

The raw material 130 may include silicon and carbon. In detail, the raw material 130 may be a compound including silicon, carbon, oxygen, and hydrogen. In more detail, the raw material 130 may be polymer including silicon and carbon. For example, the raw material 130 may be the polycarbosilane.

Referring to FIG. 3, the polycarbosilane is a kind of polysilane and includes polymer comprised of silicon and carbon atoms having the backbone structure. The polycarbosilane is a pre-ceramic raw material, which is used as a raw material of a high-strength fiber used under the ultra high temperature and having a fine diameter, such as a silicon carbide fiber. Since the polycarbosilane, which is polymer, can be easily processed in various shapes, the polycarbosilane may be applied to various applications, such as a fibrous material, a film raw material, a porous material, or a coating. In the apparatus for fabricating the ingot according to the embodiment, the polycarbosilane used as the raw material 130 is a fibrous material.

When the temperature of the polycarbosilane is maintained at the high temperature for several hours, the polycarbosilane is converted into a silicon carbide fiber. When the temperature of the converted silicon carbide fiber is increased to the single crystal growth temperature, SiC₂, Si₂C and Si are formed from the silicon carbide fiber.

The SiC₂, Si₂C and Si are sublimated and moved to the seed 190, such that a single crystal may be grown.

Since the polycarbosilane is a fibrous material, a problem caused by dust derived from powder may be prevented. In addition, the residual carbon may be prevented from being scattered and a fill factor of the reaction raw material may be attenuated, so that the reaction can be induced more smoothly and uniformly.

Since the fibrous polycarbosilane is used as the raw material, the raw material may be completely exhausted. Thus, in a process, the single crystal can be produced proportionally to the supplied raw material. Further, since the raw material is completely exhausted after producing the single crystal, it is not necessary to recovery and reuse the raw material, thereby preventing the cumbersome of the user.

Further, since the polycarbosilane is a fibrous material, a silicon carbide sublimation reaction for growing the single crystal from an end of the fibrous material may be more effectively generated. Thus, a single crystal growth rate may be improved.

Then, an upper cover 140 may be placed on an upper portion of the crucible 100. The upper cover 140 may seal the crucible 100. The upper cover 140 may include graphite.

The seed holder 160 is placed at a low end portion of the upper cover 140. The seed holder 160 may fix the seed 170. The seed holder 160 may include graphite having a high density.

The seed 170 is attached to the seed holder 160. By attaching the seed 170 to the seed holder 160, a grown single crystal may be prevented from growing to the upper cover 140. However, the embodiment is not limited thereto and the seed 170 may be directly attached to the upper cover 140.

The focusing tube 180 is placed in the crucible 100. The focusing tube 180 may be placed at a portion on which the single crystal is grown. The focusing tube 180 narrows a transfer passage of a sublimated silicon carbide gas, such that diffusion of the sublimated silicon carbide is concentrated on the seed 170. Thus, a growth rate of the single crystal may be increased.

The thermal insulator 200 surrounds the crucible 100. The thermal insulator 200 maintains the temperature of the crucible 100 at the crystal growth temperature. Since the crystal growth temperature of silicon carbide is very high, a graphite felt may be used for the thermal insulator 200. In detail, the graphite felt used for thermal insulator 200 may be manufactured in a cylindrical shape at a predetermined thickness by pressing a graphite fiber. Further, the thermal insulator 200 may be formed in a plurality of layers, so that the thermal insulator 200 may surround the crucible 100.

The quartz pipe 400 is placed at a peripheral surface of the crucible 100. The quartz pipe 400 is fitted around the peripheral surface of the crucible 100. The quartz pipe 400 may prevent heat from transferring from the heat generation induction part 500 to the inside of the single crystal growth apparatus. The quartz pipe 400 may be a hollow pipe shape having an empty inner space. Cooling water may be circulated in the inner space of the quartz pipe 400.

The heat generation induction part 500 is placed out of the crucible 100. For example, the heat generation induction part 500 may be a high frequency induction coil. The crucible 100 may be heated as a high frequency current flows through the high frequency induction coil. That is, the raw material 130 which is received in the crucible 100 may be heated at a desired temperature.

The central portion, which is induction heated in the heat generation induction part 500, is formed at a position lower than the central portion of the crucible 100. Thus, the temperature gradient may be formed in the crucible 100 such that an upper portion and a low portion of the crucible 100 may have temperatures different from each other. That is, a hot zone (HZ), which is the center of the heat generation induction part 500, is located at a low position relative to the center of the crucible 100 so that the temperature of the low portion of the crucible 100 is higher than that of the upper portion of the crucible 100 about the hot zone (HZ). Further, the temperature becomes high from the central portion to the outer peripheral portion of the crucible 100. Due to the temperature gradient, the silicon carbide raw material 130 is sublimated and the sublimated silicon carbide gas moves to a surface of the seed 170 having the relatively low temperature. Thus, the silicon carbide gas is grown in a single crystalline structure through the recrystallization.

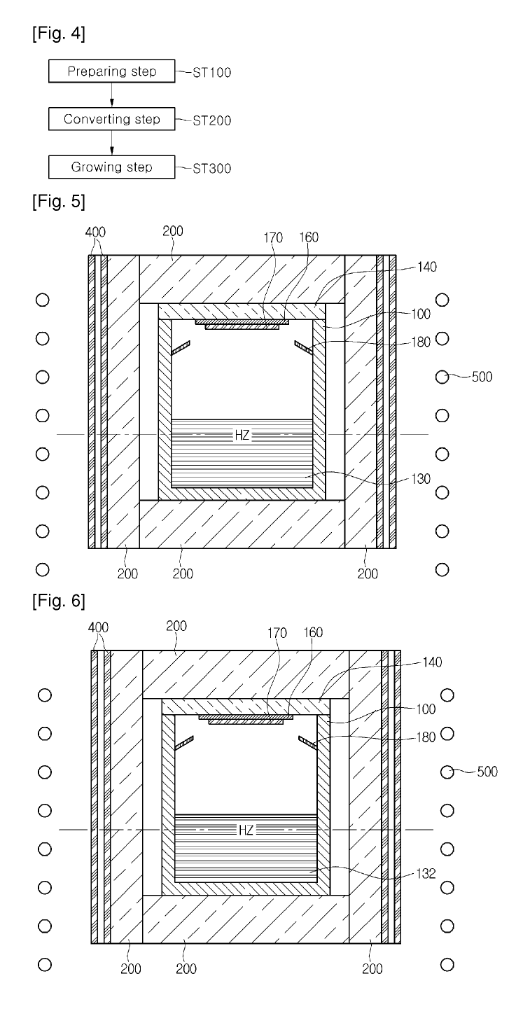

Hereinafter, the method for fabricating the ingot according to the embodiment will be described with reference to FIGS. 4 to 7. In the following description, for the purpose of clear and simple explanation, the details of structures and components the same as those in the above description or extremely similar to those in the above description will be omitted and only different parts will be described in detail.

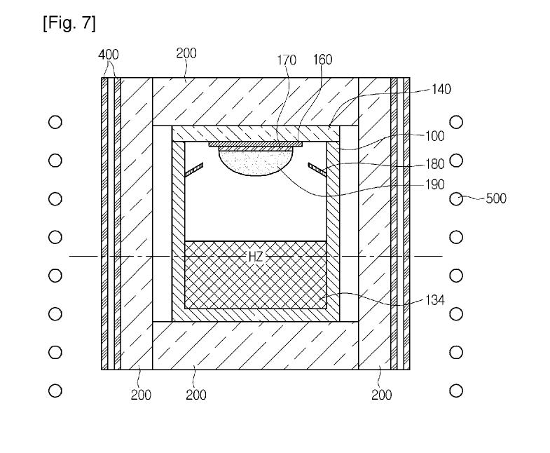

FIG. 4 is a flowchart showing the method for fabricating the ingot according to the embodiment. FIGS. 5 to 7 are sectional views illustrating the method for fabricating the ingot according to the embodiment.

The method for fabricating the ingot according to the embodiment includes a preparing step ST100, a converting step ST200 and a growing step ST300.

Referring to FIG. 5, in the preparing step ST100, the compound 130 including silicon and carbon may be prepared. For example, the compound 130 may be polycarbosilane having a fibrous shape. The fibrous polycarbosilane may be fabricated by one of typical melt spinning, melt-blown and electro spinning methods. However, the embodiment is not limited thereto, and the fibrouspolycarbosilane may be fabricated by various methods.

A stabilization process may be performed using a conventional method after stacking the fibrous polycarbosilane in the crucible 100.

Referring to FIG. 6, in the converting step ST200, the fibrous polycarbosilane may be converted into a silicon carbide fiber 132. The converting step ST200 may include a step of heat-treating the polycarbosilane in an inert gas atmosphere or a vacuum atmosphere. The heat-treating may be performed at the temperature of 800° C. in a vacuum, nitrogen, hydrogen, or argon gas atmosphere. When the temperature of the polycarbosilane is maintained for several hours, an organic-to-inorganic conversion occurs through the pyrolysis of the polycarbosilane. Then, the polycarbosilane is converted into the silicon carbide fiber 132. The silicon carbide fibers 132 converted through the embodiment are stacked on top of each other in the longitudinal direction and constitute one structure through a partial combination thereof.

Then, the temperature may be increased to and maintained at 1400° C., such that desired atoms may be doped. For example, when an N-doped single crystal is necessary, a nitrogen atmosphere treatment may be performed at the temperature in the range of 1200° C. to 1400° C. while the temperature is being increased. When a P-doped single crystal is necessary, an aluminum-doped polycarbosilane fiber may be prepared in the preparing step ST100.

Referring to FIG. 7, in the growing step ST300, sublimation may occur on a surface of the silicon carbide fiber. That is, when the silicon carbide fiber is heated to a single crystal growth temperature, SiC₂, Si₂C and Si are formed from the silicon carbide fiber.

The SiC₂, Si₂C and Si may be sublimated and moved to the seed 170, such that the single crystal 190 can be grown.

After the graphization of the silicon carbide fiber, the single crystal is grown and the silicon carbide may remain in a porous graphite fibrous structure 134.

A process time may be reduced and a process may be simplified by using the polycarbosilane instead of conventional SiC powder. This is because a conventional synthesis process for fabricating SiC powder can be omitted. That is, by using the polycarbosilane as the raw material, the synthesis and growth of the silicon carbide raw material may be simultaneously performed.

Further, after synthesizing the SiC powder, the raw material can be prevented from being contaminated when the SiC powder is filled in the crucible. Therefore, impurities can be prevented from being introduced into the single crystal, so that a high-quality single crystal can be grown.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An apparatus for fabricating an ingot, the apparatus comprising:
a crucible for receiving a raw material, wherein the raw material has a shape extending in one direction.

2. The apparatus of claim 1, wherein the raw material is a compound comprising silicon and carbon.

3. The apparatus of claim 1, wherein the raw material is a compound comprising silicon, carbon, oxygen, and hydrogen.

4. The apparatus of claim 2, wherein the raw material is polymer comprising silicon and carbon.

5. The apparatus of claim 4, wherein the raw material is polycarbosilane.

6. The apparatus of claim 1, wherein the raw material has a column shape.

7. The apparatus of claim 6, wherein the raw material has a fibrous shape.

8. The apparatus of claim 1, wherein the extending shape has a length longer than a diameter thereof.

9. The apparatus of claim 8, wherein the diameter is in a range of 0.1 μm to 500 μm.

10. The apparatus of claim 1, wherein an empty space exists between raw materials.

11. The apparatus of claim 10, wherein the raw material has a fill factor in a range of 10% to 90% in the crucible.

12. A method for fabricating an ingot, the method comprising:
preparing a compound comprising silicon and carbon;
converting the compound into a silicon carbide fiber; and
growing the silicon carbide fiber in a single crystalline structure.

13. The method of claim 12, wherein the compound comprises polycarbosilane.

14. The method of claim 12, wherein the preparing of the compound comprises stabilizing the compound.

15. The method of claim 12, wherein the converting of the compound comprises heat-treating the compound in a reduction atmosphere, an inert gas atmosphere or a vacuum atmosphere.

16. The method of claim 15, wherein the heat-treating is performed at a temperature of 600° C. to 800° C. in a vacuum, nitrogen, hydrogen, or argon gas atmosphere.

17. The method of claim 12, wherein an organic-to-inorganic conversion occurs during the converting of the compound.

18. The method of claim 12, wherein the growing of the silicon carbide fiber comprises rising a temperature of the crucible.
